(19) United States
(12) Patent Application Publication
(10) Pub. No.: US 2012/0302446 A1
(43) Pub. Date: Nov. 29, 2012

(54) JOSEPHSON MAGNETIC SWITCH

(76) Inventors: Valery V. Ryazanov, Chernogolovka (RU); Vitaly V. Bolginov, Chernogolovka (RU)

(21) Appl. No.: 13/359,450

(22) Filed: Jan. 26, 2012

Related U.S. Application Data
(60) Provisional application No. 61/436,563, filed on Jan. 26, 2011.

(51) Int. Cl. H01L 39/10; H01H 36/00; H01L 39/22

(52) U.S. Cl. 505/190; 257/31

(57) ABSTRACT

New type of Josephson switch based on Josephson superconductor/insulator/ferromagnet/superconductor (SIFS) junction is disclosed. This Josephson SIFS junction has a ferromagnetic (F-) barrier whose magnetization can be controlled by magnetic field pulses. The critical current of such SIFS junction can be controlled using the remanent magnetization of the junction ferromagnetic (F-) barrier. The proposed switch exploits a weakly ferromagnetic (F-) thin-film inner layer with in-plane magnetic anisotropy and small coercive field (for example, Pd_{0.99}Fe_{0.01}-thin-film barrier). A Nb—Pd_{0.99}Fe_{0.01}—Nb SFS sandwich can be switched between two states of Jesephson critical currents or between zero-resistance and resistive states by magnetic field pulses. It is important that the critical current states remain unchanged for a sufficient length of time at low temperatures without any applied magnetic field. The proposed Josephson magnetic switch can be used as a switching element or as an element in memory devices compatible with superconducting Single Flux Quantum digital circuits.

### BACKGROUND

The present invention relates to cryoelectric devices and, more specifically, it relates to cryoelectric switches where threshold of resistive switching can be controlled using magnetic field pulses via control current lines. As an example, such switches can be used as switching elements, as elements of memory devices compatible with superconducting Single Flux Quantum (SFQ) digital circuits or for other applications. The Josephson switch of the present invention allows to build large capacity cryogenic memory and other devices for SFQ-circuit engineering that provide for such advantages as small-area cells, non-destructive readout, fast, low power and are compatible with SFQ-fabrication process.

There has been a long need for fast and dense superconducting memories. For example, authors of one article have proposed to combine a fast Josephson structure and a separate ferromagnetic dot. R. Held, J. Xu, A. Schmehl, C. W. Schneider, J. Mannhart, and M. R. Beasley, “Superconducting memory based on ferromagnetism.” Appl. Phys. Lett. 89, 163509 (2006). The memory element uses the dot magnetization control for the storage of data and a conventional tunnel Josephson junction for data readout. In addition, a magnetic switch was proposed in a Japanese patent (JP 3190175, YUZURIHARA et al Aug. 20, 1991) that also uses a conventional Josephson junction as a magnetic flux detector and an antiferromagnetic film outside the junction to cause and maintain magnetic flux applied to the junction.

The present invention allows a combined superconductor/ferromagnet memory element to be significantly more compact if a superconductor (S) and a ferromagnet (F) are packaged in a multilayered Josephson SFS structure, wherein the ferromagnet is located between superconductor layers.

Considerable interest in metallic multilayered systems with alternating magnetic and nonmagnetic layers has been caused in large part by discovery and use of Giant Magnetic Resistance structures based on magnetic and normal metallic layered structures An example of such application is described in the following publications: P. Grünberg, J. A. Wolf, R.Schäfer, “Long Range Exchange Interactions in Epitaxial Layered Magnetic Structures.” Physica B 221 (1996) 357; U.S. Pat. No. 4,949,039 “Magnetic field sensor with ferromagnetic thin layers having magnetically antiparallel polarized components”.

Significant interest has also been developed in superconductor/ferromagnet (SF-) multilayered systems based on the coexistence of superconductivity and ferromagnetism. The antagonism of these two phenomena that differ in spin ordering is a cause of the strong suppression of superconductivity in the contact area of the S- and F-materials. However, the use of weak ferromagnets allows to realize Josephson SFS structures. In addition, the superconducting order parameter does not simply decay into the ferromagnet but also oscillates, as described in the following publication: A. I. Buzdin, “Proximity effects in superconductor/ferromagnet heterostructures.” Rev. Mod. Phys. 77 (2005) 935.

The first observation of the superconducting current through a Josephson SFS junction is described by V. V. Ryazanov in “Josephson superconductor- ferromagnetic-superconductor π-contact as an element of a quantum bit.” Phys. Usp. 42 (1999) 825.

Specific features of Josephson SFS junctions have been used for implementation of superconducting phase inventors. V. V. Ryazanov, V. A. Oboznov, “Device for the superconducting phase shift” Patent RU 97567 (2010); A. K. Feofanov, V. A. Oboznov, V. V. Bol'ginov, J. Lisenfeld, S. Poletto, V. V. Ryazanov, A. N. Rossolenko, M. Khabipov, D. Balashov, A. B. Zorin, P. N. Dmitriev, V. P. Koshelets and A. V. Ustinov, “Implementation of superconductor/ferromagnet/superconductor pi-shifters in superconducting digital and quantum circuits.” Nature Physics 6 (2010) 593.

The magnetic structure of a ferromagnetic (F-) inner layer in the SFS phase inverter must be stable at small changes of magnetic field and currents in the circuit to ensure stable phase shift. The present invention proposes to apply remagnetization of an F-barrier in a Josephson SFS junction (with single ferromagnetic barrier) to maintain and switch the junction critical current states.

The realization of the spin-valve effect by manipulating the mutual orientations of the magnetizations of ferromagnetic (F-) layers in a multilayered FSF system has also been described. G. Deutscher and F. Meunier, “Coupling Between Ferromagnetic Layers Through a Superconductor.” Phys. Rev. Lett 22 (1969) 395. The authors measured a difference in the superconducting transition temperature T_{c} between antiparallel (AP) and parallel (P) orientations of the F-layer magnetizations using transport resistive (in-plane) experiment on the FSF (FeNi/In/Ni) trilayer. They have observed a lower T_{c} for P-orientation.

A theoretical description of this phenomenon was carried out by L. R. Tagirov in “Low-Field Superconducting Spin Switch Based on a Superconductor/Ferromagnet Multilayer.” Phys. Rev. Lett 83 (1999) 2058.

The mean exchange field from two F-layers acting on superconducting Cooper pairs in the S-layer is smaller for the AP magnetization orientation of F-layers compared with the P-case. The spin-valve effect with full switching of a SFF′ trilayer from the resistive state (for P-orientation) to the superconducting one (for AP-orientation) has also been observed. P. V. Leksin, N. N. Garif'yanov, I. A. Garifullin, J. Schumann, H. Vinzelberg, V. Kataev, R. Klingeler, O. G. Schmidt, and B. Büchner, “Full spin switch effect for the superconducting current in a superconductor/ferromagnet thin film heterostructure.” Appl. Phys. Lett. 97 (2010) 102505.

The case of non-collinear orientations of the F-layer magnetizations was also described. A. I. Buzdin, A. V. Vedyaev, and N. N. Ryzhanova, “Spin-orientation-dependent superconductivity in F/S/F structures.” Europhys. Lett. 48 (1999) 686. The authors in that reference took into account only the conventional (spin-singlet pair component). In. addition to that, it was predicted that noncollinear F-layer magnetizations in multilayered FS-structures result in a new “spin-triplet pair component” appearance, which penetrates deep into a ferromagnet due to the long-range superconducting proximity effect. F. S. Bergeret, A. F. Volkov, and K. B. Efetov, “Enhancement of the Josephson Current by an Exchange Field in Superconductor-Ferromagnet Structures” Phys. Rev. Lett. 86 (2001) 3140; “Odd triplet superconductivity and related phenomena in superconductor-ferromagnet structures.” Rev. Mod. Phys. 77 (2005) 1321.

The FSF spin-valve behaviour related to the spin-triplet pair component has been described. Ya. V. Fominov, A. A. Golubov and M. Yu. Kupriyanov, “Triplet proximity effect in FSF trilayers”. JETP Lett. 77 (2003) 510.

Josephson SFIFS and SFNFS spin-switches were proposed in a number of publications. V. N. Krivoruchko and E. A. Koshina, “From inversion to enhancement of the dc Josephson current in S/F-I-F/S tunnel structures.” Phys. Rev. B 64 (2003) 172511; T. Yu. Karminskaya, M. Yu. Kupriyanov and A. A. Golubov, “Critical current in S-FNF-S Josephson structures with the noncollinear magnetization vectors of ferromagnetic films.” JETP Lett., 87 (2008) 570; T. Yu. Karminskaya, M. Yu. Kupriyanov and V. V. Rjazanov. “Superconducting device with Josephson junction”, Patent RU 2373610 C1.

All these propositions use variations in the Josephson critical current magnitude due to changes of mutual magnetization orientations of two F-layers separated by a nonmagnetic normal metal (N) or a dielectric (I) spacer layer. The need to use two ferromagnetic layers in a single domain state is a substantial disadvantage of these devices.

### SUMMARY

The following is a summary description of illustrative embodiments of the present invention. It is provided as a preface to assist those skilled in the art to more rapidly assimilate the detailed design discussion which ensues and is not intended in any way to limit the scope of the claims, which are appended hereto in order to particularly point out the invention.

The object of this invention is a new type of Josephson switch based on superconductor/insulator/ferromagnet/superconductor (SIFS) junction with one multidomain or single domain ferromagnetic inner layer and the critical current controlled by magnetization changing of the ferromagnetic inner layer (F-barrier). The F-barrier is a weak link which ensures a Josephson effect, i.e. possibility of the supercurrent flow through the ferromagnetic inner layer between two superconducting (S-) layers. The proposed device is shown schematically in FIG. 1. It contains an Josephson SIFS junction 1 inductively coupled with control current line 6 for supplying magnetic field pulses. The pulses change the remanent magnetization of the F-layer. Due to the magnetization changing, the net magnetic inductance B of the F-barrier 3 varies and shifts the junction critical current value I, in accordance with the “Fraunhofer” Iₑ(B) dependence of Josephson junction (see, for example, A. Barone, G. Paterno, “Physics and Applications of the Josephson Effect”, Wiley-Interscience Publication, 1982, Ch. 4).

Using magnetic field pulses SIFS junction can be switched repeatedly between two stable states having different values of the critical current L. In presence of a constant “readout current”, I_{read}, through the SIFS junction, the device switches between the superconducting (zero-resistance) and resistive states. It is important that the critical current states remain substantially unchanged for a sufficiently long period of time at low temperatures without any applied magnetic field.

FIG. 2 shows how the critical current depends from the magnetic field in a Nb—Pd_{0.99}Fe_{0.01}—Nb sandwich-like structure with weak ferromagnetic Pd_{0.99}Fe_{0.01}-barrier at the temperature equal to T=4.2 K. The arrows show the direction of the applied magnetic field cycling. FIG. 2 demonstrates that I_{c}(H)-behavior is reversible and the extreme right and left states correspond to different critical current values. The remagnetization loop for the I_{c}(H)-dependence has two critical current values at zero magnetic field. Thus, it's possible to choose the bias current amount (I_{read}=240 μA in FIG. 2) to switch the SFS junction from a superconducting to a resistive state by a pulse of weak magnetic field. The result of such an experiment is presented in FIG. 3, where positive and negative magnetic field pulses switch the SFS junction from a superconducting (zero-resistance) state to the resistive one and back to the superconducting state.

To increase the speed of the switch, one has to reduce the inductance of a control current line 6, as shown in FIG. 1, and the switching time of the Josephson junction τ_{J}=Φ₀/(2π) I_{c}Rₙ,), where Φ₀ is magnetic flux quantum, I_{c} is the junction critical current and Rₙ is the junction normal resistance. Using an additional tunnel layer I in the junction (i.e. fabrication SIFS sandwich with additional insulator inner layer) enables an increase V_{c}=I_{c}Rₙ up to 10⁻⁴ V and a significant reduction of the switching time. The results of an experiment with SIFS (Nb—AlOₓ—Pd_{0.99}Fe_{0.01}—Nb) junction are presented in FIGS. 4 and 5.

### BRIEF DESCRIPTION OF THE DRAWINGS

FIG. 1 shows the Josephson magnetic switch of the present invention.

FIG. 2 presents a magnetic field dependence of the critical current I_{c}(H) for a Nb—Pd_{0.99}Fe_{0.01}—Nb SFS Josephson junction with a weak ferromagnetic Pd_{0.99}Fe_{0.01}-inner layer.

FIG. 3 shows the timing diagram of the magnetic field pulses and the corresponding switching of the SFS junction from superconducting (zero-resistance) state to the resistive state.

FIG. 4 shows the I-V characteristic of an SIFS (Nb—AlOₓ—Pd_{0.99}Fe_{0.01}—Nb) junction with V_{c}=I_{c}Rₙ=10⁻⁴ V and temperature T=2.2 K.

FIG. 5 shows a timing diagram of magnetic field pulses and the corresponding switching of an SIFS (Nb—AlOₓ—Pd_{0.99}Fe_{0.01}—Nb) junction from the superconducting (zero-resistance) state to the resistive state.

### DETAILED DESCRIPTION OF THE INVENTION

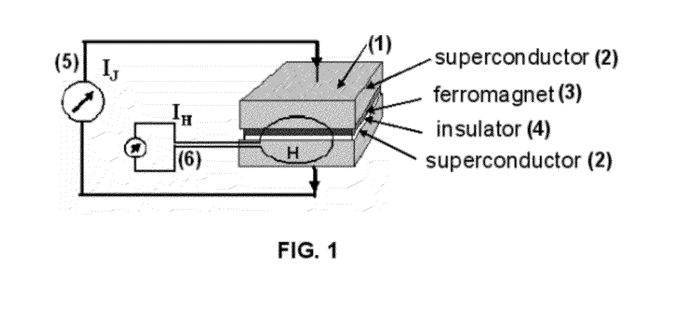

FIG. 1 presents the Josephson Magnetic Switch (JMS) of the present invention. The JMS comprises a multilayered superconductor/insulator/ferromagnet/superconductor (SIFS) Josephson junction 1 with a multidomain or single-domain ferromagnetic inner layer (F-barrier) 3 and an insulator (I) inner layer 4 sandwiched between two superconducting layers (S-electrodes) 2. The IF-barrier is a weak link which allows the Josephson effect, i.e. the possibility of the superconducting current flow between the S-electrodes.

The JMS of the present invention also comprises a bias current circuit 5, which applies a bias junction current, and a magnetic pulse circuit 6, which is the control current line for supplying magnetic field pulses. Bias circuit 5 also provides control of the resistive and superconducting states of the Josephson junction 1. An additional isolator tunnel interlayer (I-barrier) allows to decrease the JMS switching time.

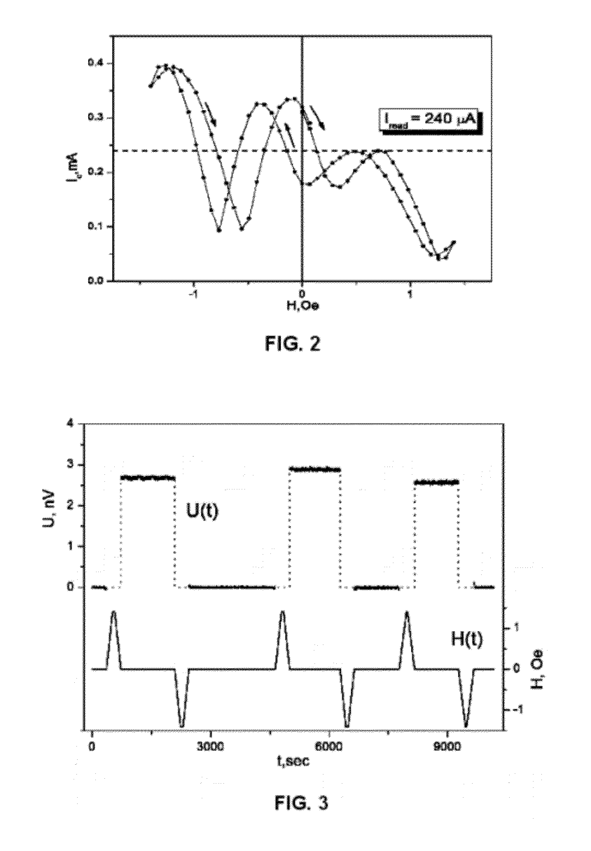

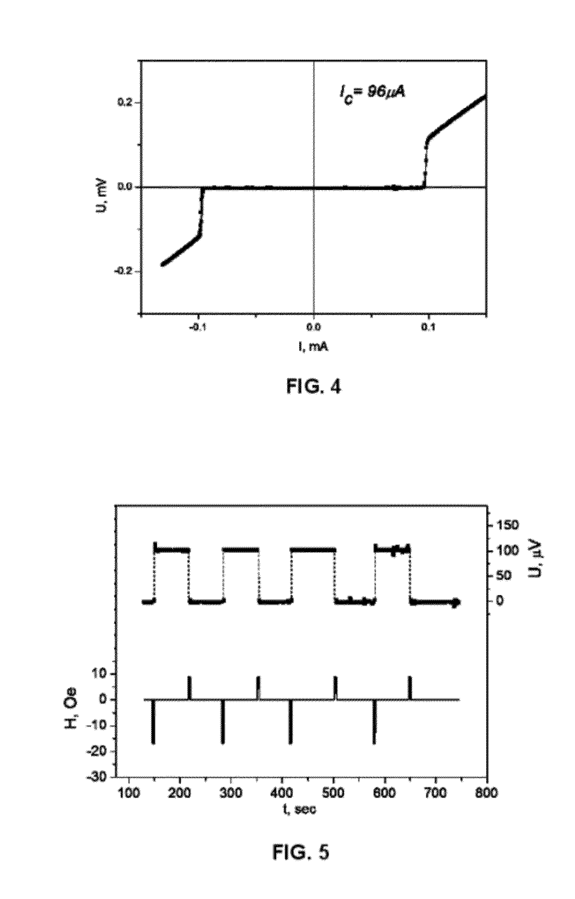

A JMS operation of the present invention is based on repeated remagnetizations of a Josephson SIFS junction ferromagnetic inner layer, whereby the junction can repeatedly switch between two stable states having different values of critical current I_{c}, as shown in FIG. 2. In case of uniform magnetization a Josephson SIFS junction has a quasi-periodical (“Fraunhofer”) dependence of the critical current I_{c} vs. magnetic flux Φ through the junction area:

I_{c}(Φ)=I_{c0}sin(πΦ/Φ₀)/(πΦ/Φ₀).

Here Φ=BdₘL, B is an average magnetic induction of the ferromagnetic inner layer, dₘ is the “magnetic thickness” of the Josephson junction, L is the junction size in the direction perpendicular to the average magnetic induction B, Φ₀ is magnetic flux quantum).

Here Φ=BdₘL, B is an average magnetic induction of the ferromagnetic inner layer, dₘ is the “magnetic thickness” of the Josephson junction, L is the junction size in the direction perpendicular to the average magnetic induction B, Φ₀ is magnetic flux quantum.

At zero external magnetic field the critical current value I_{c}(H=0) depends on the remanent magnetization value M. In the virgin state M equals zero and magnetic flux Φ equals zero too. Magnetization from the virgin state with an averaged domain structure to the saturation magnetization of a ferromagnetic inner layer and remagnetization from the uniform saturated state to the remanent magnetization results in sharp changes of the “zero-field” critical current needed for the JMS functioning.

In addition, SIFS junctions with submicron single domain barriers can be used as Josephson magnetic switches too, i.e. it is possible to realize a Josephson magnetic switch with a single-domain F-barrier. To accomplish that, it would be necessary to have an SIFS junction with a specified easy axis of F-layer. For example, a rectangular F-layer with an easy axis along the long side a and a metastable magnetic state along short side b˜a/2 would be convenient. If the saturation magnetic flux density is B_{S} and the ferromagnetic layer thickness is d, magnetic flux through the junction will equal Φ₁˜Bdb in the initial state when the direction of B_{S} coincides with the easy axis and Φ₂=Bda in the metastable state when B is directed along the b axis. The critical currents can differ significantly in these two states.

The Josephson Magnetic Switch of the present invention based on the F-layer remagnetization use weakly ferromagnetic alloy with in-plane magnetic anisotropy that provides small decay of superconductivity and non-zero magnetic flux through a junction at a zero magnetic field. Weak and soft-magnetic PdFe alloy with low Fe-content can be used for this purpose. C. Büscher, T. Auerswald, E. Scheer E, et al., Phys Rev B 46 (1992) 983. For example, a thin layer of Pd_{0.99}Fe_{0.01}-alloy with thickness of 34 nm has Curie temperature of about 15 K.

FIGS. 2 anb3 show how an SFS junction with such barrier operates as a Josephson magnetic switch. Due to in-plane magnetic anisotropy and small coercive field, magnetic field pulses with amplitude of only about 1 Oe are enough to switch the SFS junction from superconducting state to a resistive state and vice versa. The F layer of the foregoing JMS is characterized by magnetic domain size of about 8-10 μm and the saturation field of about 5-10 Oe. Therefore, the junction with lateral sizes 30×30 μm² (FIGS. 2,3) operates due to remagnetization of domain structures.

When SFS junction sizes approach the domain size, two branches of I_{c}(H)-dependence for positive and negative field signs become symmetric relative to the point of origin, so that the critical current values for positive and negative remanent magnetizations coincide. To realize two different states, it is necessary to use different amplitudes of positive and negative pulses (as shown in FIG. 5) or to apply additional DC-field offset.

An example of the fabrication process starts from a Nb—PdFe—Nb (or Nb—Al/AlOₓ—PdFe—Nb) multilayer deposition in a single vacuum cycle. First, an Nb-layer (or Nb—Al bilayer) of 120 nm Nb (and 10 nm Al) thickness is deposited by means of the magnetron sputtering. In case of SIFS junction, Al layer is oxidized for 30 min in an oxygen atmosphere at 1.5×10⁻² mBar. These fabrication parameters allow to provide for transparency of a tunnel barrier appropriate for the critical current density of 4 kA/cm². Then oxygen is pumped off and PdFe—Nb bilayer is deposited using an rf- and dc magnetron sputtering. A Pd_{0.99}Fe_{0.01}-layer with a thickness of about 30 nm can be used for SFS junctions and a thickness of about of 12-15 nm can be used for SIFS junctions.

The top Nb layer thickness can be greater (approximately 120-150 nm) to ensure a uniform supercurrent flow through the Josephson junction. At the second step, a square “mesa” of 30×30 or 10×10 μm² can be formed by photolithography process, RIE etching of top Nb layer and argon plasma etching of PdFe and Al/AlOx layers.

Then the bottom Nb-electrode can be patterned using a photolithography and RIE etching processes. At the third step, an isolation layer with a window can be formed by application of thermal evaporation of SiO and a lift-off process.

At the last step, an Nb wiring electrode with the thickness of 450 nm can be formed using magnetron sputtering and lift-off lithography processes.

The manufacturing technique described above is compatible with the modern Nb—AlOx technology of SFQ-circuit fabrication.

The switch speed of the Josephson memory element built pursuant to the present invention depends from the inductance of a magnetic pulse control current line and the switching time of the SIFS junction. The latter is τ_{J}=(2πI_{c}Rₙ). The attained value of I_{c}Rₙ˜10⁻⁴ V corresponds to the switching rate of a conventional Josephson tunnel junction about of 100 GHz. Thus, a limiting switching frequency is restricted by F-layer remagnetization rate. The best result appears to be ensured by remagnetization of a small single domain ferromagnetic barrier.

The foregoing description of various embodiments of the invention has been presented for purposes of illustration and description. Many modifications and variations are possible. Such modifications and variations that may be apparent to a person skilled in the art are intended to be included within the scope of the appended claims.

What we claim is:

1. A Josephson magnetic switch comprising:
a multilayered superconductor/insulator/ferromagnet/superconductor (SIFS) Josephson junction, wherein a first outer layer is made of a first superconducting material, a second outer layer is made of a second superconducting material, a first inner layer is made of a ferromagnet and a second inner layer is made of an insulator material;
a bias current circuit; and
a magnetic pulse control current line.

2. A Josephson magnetic switch of claim 1, wherein said first outer layer and said second outer layer are made of the same superconducting material.

3. A Josephson magnetic switch of claim 1, wherein said first inner layer is made of a multidomain ferromagnet.

4. A Josephson magnetic switch of claim 1, wherein said first inner layer is made of a single domain ferromagnet.

5. A Josephson magnetic switch of claim 1, wherein said ferromagnet is characterized by a hysteresis width that is greater than zero.

6. A Josephson magnetic switch of claim 1, wherein said magnetic pulse control line is capable of providing magnetic field pulses for remagnetizing said ferromagnet.
